(19) United States
(12) Patent Application Publication
(10) Pub. No.: US 2020/0144033 A1
(43) Pub. Date: May 7, 2020

(54) LOWER ELECTRODE AND DRY ETCHING MACHINE

(71) Applicant: WUHAN CHINA STAR OPTOELECTRONICS TECHNOLOGY CO., LTD., Wuhanm Hubei (CN)

(72) Inventor: Liming JI, Wuhan (CN)

(21) Appl. No.: 16/336,106

(22) PCT Filed: Aug. 6, 2018
(86) PCT No.: PCT/CN2018/098931

§ 371 Date: Mar. 24, 2019

(51) Int. Cl. H01J 37/32

(52) U.S. Cl. CPC H01J 37/32559; H01J 2237/334; H01J 37/3255; H01J 37/32715

(57) ABSTRACT

A lower electrode and a dry etching machine including the lower electrode are provided. The lower electrode includes a base layer, a carrier layer, a bolt, and a sealing member. The sealing member includes a sealing body and a through hole. The carrier layer includes a connecting hole and a first counterbore. The bolt sequentially passes through the through hole and the connecting hole and is screwed with the base layer. The sealing body and a nut of the bolt are disposed in the first counterbore. The sealing body completely covers an opening of the connecting hole, so as to prevent plasma from entering the connecting hole and causing the lower electrode to be injured.

### FIELD OF INVENTION

The present disclosure relates to the field of dry etching technologies, and more particularly to a lower electrode and a dry etching machine including the lower electrode.

### BACKGROUND OF INVENTION

With the development of the information society, demands for display devices have been increasing, which have promoted a rapid development of a liquid crystal liquid (LCD) panel industry, and an output of panels has been continuously improved. Etching process is an important step in a process of fabricating an array substrate of a thin film transistor LCD device. The etching process is classified into a dry etching process and a wet etching process according to a physical state of an etchant.

The dry etching process generates plasma using an etching gas and a radio frequency (RF) electrode and removes a film that is not covered and protected by a photoresist on a glass substrate using chemical reaction and physical reaction to complete a transfer of a mask pattern to the film.

In an existing lower electrode for a dry etching machine, as illustrated in FIG. 1, the lower electrode includes a base layer 11′, a ceramic layer 12′ configured to support a glass substrate and disposed on the base layer 11′, a bolt 13′ fixedly connected to the ceramic layer 12′ and the base layer 11′, and a washer 14′ sleeved on the bolt 13′. The ceramic layer 12′ includes a connecting hole 121′ for the bolt 13′ to pass through and a first counterbore 122′ disposed on the connecting hole 121′. The washer 14′ is disposed between a nut of the bolt 13′ and the first counterbore 122′.

As illustrated in FIG. 2, when a dry etching is performed, since the washer 14′ is annular, the first counterbore 122′ is an oblong hole, the washer 14′ cannot completely cover the connecting hole 121′, such that a ceramic cover 15′ is not tightly covered. Plasma enters the first counterbore 122′ and the connecting hole 121′, and reacts with the base layer 11′, causing the base layer 11′ to be injured, thereby causing the dry etching machine to malfunction and causing a decrease in productivity.

### SUMMARY OF INVENTION

An object of an embodiment of the present disclosure is to provide a lower electrode of a dry etching machine and the dry etching machine to solve technical problems that when an existing lower electrode is subjected to dry etching, plasma enters a connecting hole and reacts with a base layer, thereby causing the base layer to be injured.

To achieve the above object, an embodiment of the present disclosure provides a lower electrode including a base layer, a carrier layer, a bolt, and a sealing member. The carrier layer is configured to support an external glass substrate. The bolt fixedly connects the base layer and the carrier layer. The sealing member is sleeved on an outer peripheral side of the bolt. The sealing member includes a sealing body and a through hole disposed in the sealing body, and the bolt is adapted to pass through the through hole. The carrier layer includes a connecting hole and a first counterbore communicating with an end of the connecting hole facing away from the base layer, and the bolt is adapted to pass through the connecting hole. The bolt sequentially passes through the through hole and the connecting hole and is screwed with the base layer. The sealing body and a nut of the bolt are disposed in the first counterbore. The sealing body completely covers an opening of the connecting hole, a shape of the sealing body is same as a shape of the first counterbore, and the sealing body is disposed in the first counterbore in an interference fit. The seal member is made of polyetheretherketone.

In an embodiment of the present disclosure, the sealing member includes a receiving groove recessed in an end of the sealing body facing away from the base layer and communicating with the through hole, and the nut of the bolt is disposed in the receiving groove.

In an embodiment of the present disclosure, a thickness of the sealing member is same as a depth of the first counterbore.

In an embodiment of the present disclosure, the lower electrode further includes a sealing cover, the carrier layer includes a second counterbore disposed at an end of the first counterbore facing away from the base layer, and the sealing cover is sealingly disposed in the second counterbore.

In an embodiment of the present disclosure, the base layer is an electrode, the carrier layer is a ceramic layer, the bolt is an insulating bolt, and the sealing cover is a ceramic cover.

An embodiment of the present disclosure further provides a lower electrode including a base layer, a carrier layer, a bolt, and a sealing member. The carrier layer is configured to support an external glass substrate. The bolt fixedly connects the base layer and the carrier layer. The sealing member is sleeved on an outer peripheral side of the bolt. The sealing member includes a sealing body and a through hole disposed in the sealing body. The bolt is adapted to pass through the through hole. The carrier layer includes a connecting hole and a first counterbore communicating with an end of the connecting hole facing away from the base layer, and the bolt is adapted to pass through the connecting hole. The bolt sequentially passes through the through hole and the connecting hole and is screwed with the base layer. The sealing body and a nut of the bolt are disposed in the first counterbore. The sealing body completely covers an opening of the connecting hole.

In an embodiment of the present disclosure, a shape of the sealing body is same as a shape of the first counterbore, and the sealing body is disposed in the first counterbore in an interference fit.

In an embodiment of the present disclosure, the seal member is made of polyetheretherketone.

In an embodiment of the present disclosure, the sealing member includes a receiving groove recessed in an end of the sealing body facing away from the base layer and communicating with the through hole, and the nut of the bolt is disposed in the receiving groove.

In an embodiment of the present disclosure, a thickness of the sealing member is same as a depth of the first counterbore.

In an embodiment of the present disclosure, the lower electrode further includes a sealing cover, the carrier layer includes a second counterbore disposed at an end of the first counterbore facing away from the base layer, and the sealing cover is sealingly disposed in the second counterbore.

In an embodiment of the present disclosure, the base layer is an electrode, the carrier layer is a ceramic layer, the bolt is an insulating bolt, and the sealing cover is a ceramic cover.

An embodiment of the present disclosure further provides a dry etching machine including a reaction chamber, an upper electrode, and a lower electrode. The upper electrode is disposed at an upper portion of the reaction chamber. The lower electrode is disposed at a lower portion of the reaction chamber. The upper electrode and the lower electrode are oppositely disposed, the upper electrode is connected to a power source, and the lower electrode is grounded. The lower electrode includes a base layer, a carrier layer configured to support an external glass substrate, a bolt fixedly connecting the base layer and the carrier layer, and a sealing member sleeved on an outer peripheral side of the bolt. The sealing member includes a sealing body and a through hole disposed in the sealing body, and the bolt is adapted to pass through the through hole. The carrier layer includes a connecting hole and a first counterbore communicating with an end of the connecting hole facing away from the base layer, and the bolt is adapted to pass through the connecting hole. The bolt sequentially passes through the through hole and the connecting hole and is screwed with the base layer. The sealing body and a nut of the bolt are disposed in the first counterbore. The sealing body completely covers an opening of the connecting hole.

In an embodiment of the present disclosure, a shape of the sealing body is same as a shape of the first counterbore, and the sealing body is disposed in the first counterbore in an interference fit.

In an embodiment of the present disclosure, the seal member is made of polyetheretherketone.

In an embodiment of the present disclosure, the sealing member includes a receiving groove recessed in an end of the sealing body facing away from the base layer and communicating with the through hole, and the nut of the bolt is disposed in the receiving groove.

In an embodiment of the present disclosure, a thickness of the sealing member is same as a depth of the first counterbore.

In an embodiment of the present disclosure, the lower electrode further includes a sealing cover, the carrier layer includes a second counterbore disposed at an end of the first counterbore facing away from the base layer, and the sealing cover is sealingly disposed in the second counterbore.

In an embodiment of the present disclosure, the base layer is an electrode, the carrier layer is a ceramic layer, the bolt is an insulating bolt, and the sealing cover is a ceramic cover.

Compared to the lower electrode of the dry etching machine of existing technologies, the lower electrode and the dry etching machine of the embodiment of the present disclosure, in one hand, use the sealing member to completely cover the opening of the connecting hole, so as to improve sealing of the sealing member and prevent plasma from entering the connecting hole and causing the lower electrode to be injured. On another hand, the sealing member is made of polyetheretherketone, so as to improve high temperature resistance and compressive strength of the sealing member and avoid deformation of the sealing member during high temperature operation and sealing loss of the sealing member, which may cause the lower electrode to be injured. The embodiment also solves technical problems that when an existing lower electrode is subjected to dry etching, plasma enters the connecting hole and reacts with the base layer, thereby causing the base layer to be injured.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic cross-sectional structural view of an existing lower electrode.

FIG. 2 is a schematic top plan view of an existing lower electrode removing a ceramic cover.

FIG. 3 is a schematic cross-sectional structural view of a lower electrode according to an embodiment of the present disclosure.

FIG. 4 is a schematic top plan view of a lower electrode removing a ceramic cover according to an embodiment of the present disclosure.

FIG. 5 is a schematic top plan view of a sealing member of a lower electrode according to an embodiment of the present disclosure.

FIG. 6 is a cross-sectional view taken along line AA of FIG. 5.

FIG. 7 is a schematic structural view of a dry etching machine according to an embodiment of the present disclosure.

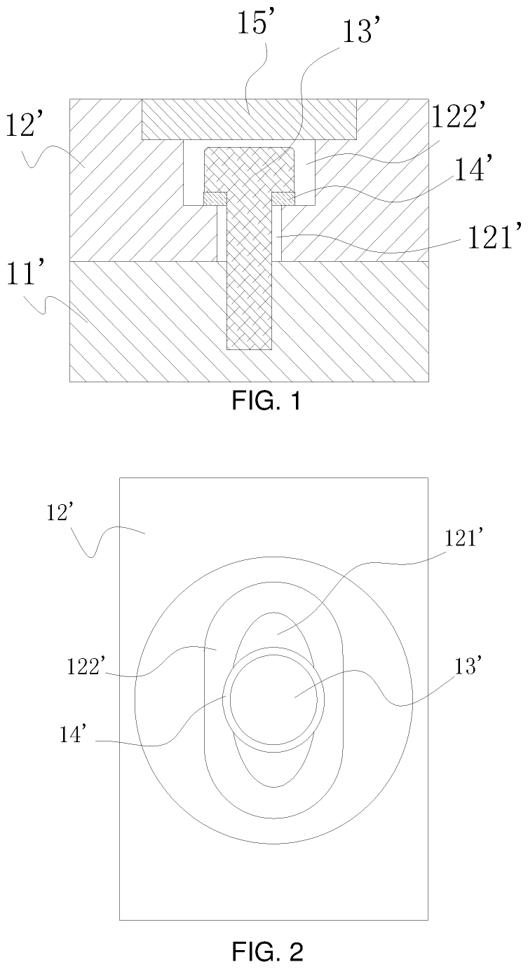

### DETAILED DESCRIPTION OF PREFERRED EMBODIMENTS

Please refer to the drawings, wherein same symbols represent same components. While the following description may contain specific details describing specific embodiments of the present disclosure, this should not be construed as limitations to other embodiments which are not described in the present disclosure.

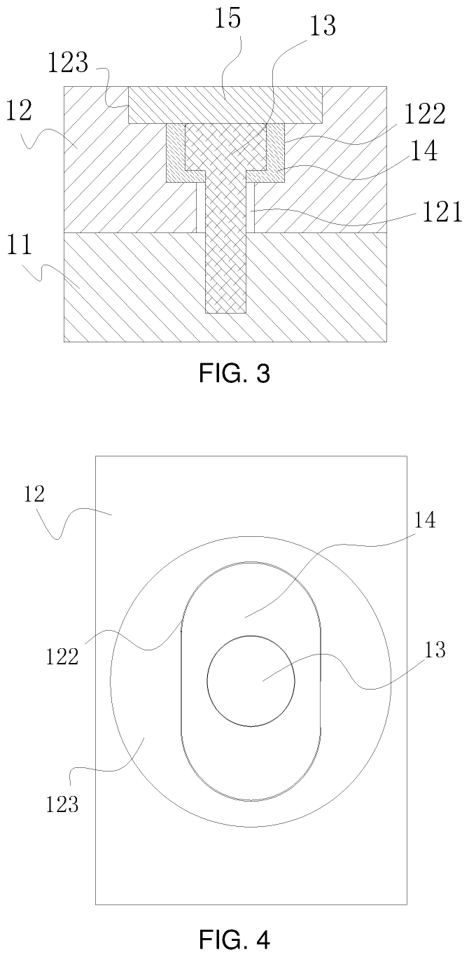

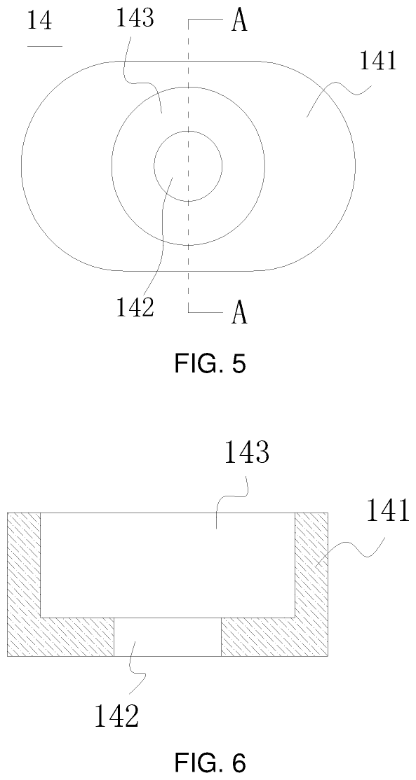

Refer to FIG. 3 to FIG. 5, wherein FIG. 3 is a schematic cross-sectional structural view of a lower electrode according to an embodiment of the present disclosure, FIG. 4 is a schematic top plan view of a lower electrode removing a ceramic cover according to an embodiment of the present disclosure, and FIG. 5 is a schematic top plan view of a sealing member of a lower electrode according to an embodiment of the present disclosure.

A lower electrode of the embodiment includes a base layer 11, a carrier layer 12 configured to support an external glass substrate, and a bolt 13 fixedly connects the base layer 11 and the carrier layer 12.

The lower electrode further includes a sealing member 14 sleeved on an outer peripheral side of the bolt 13. The sealing member 14 includes a sealing body 141 and a through hole 142 disposed in the sealing body 141, and the bolt 13 is adapted to pass through the through hole 142.

The carrier layer 12 includes a connecting hole 121 and a first counterbore 122 communicating with an end of the connecting hole 121 facing away from the base layer 11, and the bolt 13 is adapted to pass through the connecting hole 121.

The sealing body 141 and a nut of the bolt 13 are disposed in the first counterbore 122. The bolt 13 sequentially passes through the through hole 142 and the connecting hole 121 and is screwed with the base layer 11.

The sealing body 141 completely covers an opening of the connecting hole 121.

In the lower electrode of the embodiment, the sealing member 14 completely covers the opening of the connecting hole 121, such that the sealing body 141 and a bottom surface of the first counterbore 122 are more closely connected, thereby improving sealing of the sealing member 14 disposed in the first counterbore 122, so as to prevent plasma from entering the connecting hole 121 and causing the lower electrode to be injured.

Further, a shape of the sealing body 141 is same as a shape of the first counterbore 122, and the sealing body 141 is disposed in the first counterbore 122 in an interference fit.

In detail, a shape of an outer contour of the sealing body 141 in the sealing member 14 is same as a shape of a contour of a hole wall of the first counterbore 122, and an area of the outer contour of the sealing body 141 is greater than an area of the contour of the hole wall of the first counterbore 122. Such an arrangement enables an outer peripheral wall of the sealing body 141 to be force-balanced to be in a tight fit with the first counterbore 122. The sealing member 14 is disposed in the first counterbore 122 in an interference fit, so as to improve stability of tight connection of the sealing member 14 and an inner wall of the first counterbore 122.

In the embodiment, refer to FIG. 4, the sealing body 141 and the first counterbore 122 are both racetrack-shaped, but in the present disclosure, shapes of the sealing body 141 and the first counterbore 122 are not limited thereto, such as oblong, rounded rectangle, and so on.

Refer to FIGS. 5-6, in the lower electrode of the embodiment, the sealing member 14 includes a receiving groove 143 recessed in an end of the sealing body 141 facing away from the base layer 11 and communicating with the through hole 142, and the nut of the bolt 13 is disposed in the receiving groove 143.

The nut of the bolt 13 is suspended in the receiving groove 143 to save space on one hand. On another hand, when the nut of the bolt 13 is disposed in the receiving groove 143 in an interference fit, the nut of the bolt 13 is pressed against an inner wall of the receiving groove 143, such that the sealing body 141 is pressed against the hole wall of the first counterbore 122, thereby improving the sealing between the bolt 13, the sealing element 14, and the first counterbore 122.

A shape of the nut of the bolt 13 is same as a shape of the receiving groove 143. Optionally, shapes of the nut of the bolt 13 and the receiving groove 143 are both circular.

In the lower electrode of the embodiment, a thickness of the sealing member 14 is same as a depth of the first counterbore 122. Such an arrangement allows side walls of the sealing member 14 to complete covering side walls of the first counterbore 122, improving sealing of the sealing member 14 and the first counterbore 122.

In an embodiment of the present disclosure, in order to facilitate fitting the sealing member 14 in the first counterbore 122, the thickness of the sealing member 14 may also be slightly less than the depth of the first counterbore 122.

Further, in the lower electrode of the embodiment, the sealing member 14 is made of a polyetheretherketone (PEEK). PEEK polymer is a thermoplastic specialty engineering plastic having high temperature and high performance. The PEEK polymer has good mechanical strength, wear resistance, and compressive strength. The PEEK polymer has a compressive strength of 200 MPa at 120° C. and is not easily deformed. Therefore, the PEEK polymer overcomes disadvantages that the sealing element is easily deformed in an environment at a temperature of about 120° C., resulting in loss of sealing performance, thereby preventing the lower electrode from being injured.

Based on the above structure, in the lower electrode of the embodiment, the lower electrode further includes a sealing cover 15, the carrier layer 12 includes a second counterbore 123 disposed at an end of the first counterbore 122 facing away from the base layer 11, and the sealing cover 15 is sealingly disposed in the second counterbore.

In the lower electrode of the embodiment, the base layer 11 is an electrode, the carrier layer 12 is a ceramic layer, the bolt 13 is an insulating bolt, and the sealing cover 15 is a ceramic cover.

An assembly process of the lower electrode of this embodiment is as follows.

First, the base layer 11 is placed while the sealing member 14 is placed in the first counterbore 122 of the carrier layer 12.

Subsequently, a threaded hole of the base layer 11 and the connecting hole 121 of the carrier layer 12 are butted.

Then, the bolt 13 sequentially passes through the second counterbore 123, the receiving groove 143, the through hole 142, and the connecting hole 121, and is screwed with the threaded hole of the base layer 11, while the bolt 13 is disposed in the receiving groove 143.

Finally, the sealing cover 15 is sealingly disposed in the second counterbore 123 to complete the assembly process.

This completes the assembly process of the embodiment.

In addition, when the embodiment and an upper electrode cooperate to work, if the sealing cover 15 is not tightly sealed, the plasma enters the first counterbore 122. However, due to a full cover-type sealing connection of the sealing body 141 of the sealing element 14 and the first counterbore 122, the plasma does not enter the connecting hole 121, and thus the lower electrode cannot be injured.

At the same time, since the sealing member 14 has good mechanical strength, wear resistance, and compressive strength. The sealing member 14 has a compressive strength of 200 MPa at 120° C. and is not easily deformed, thereby avoiding damage and deformation of the sealing member 14 and loss of sealing performance, thereby protecting the lower electrode from being injured.

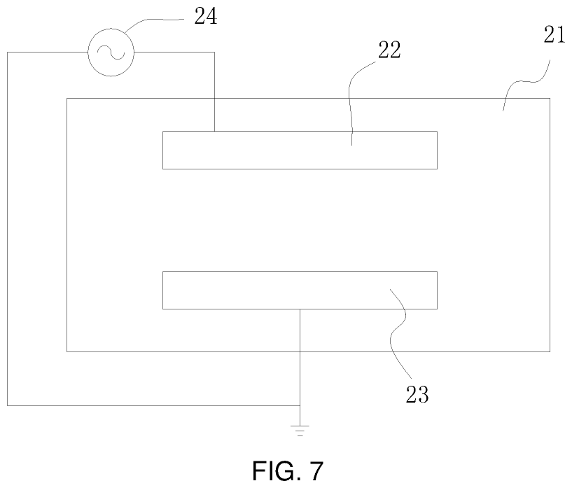

Refer to FIG. 7, an embodiment of the present disclosure further provides a dry etching machine including a reaction chamber 21, an upper electrode 22 disposed at an upper portion of the reaction chamber 21, and a lower electrode 23 disposed at a lower portion of the reaction chamber 21. The upper electrode 22 and the lower electrode 23 are oppositely disposed, the upper electrode 22 is connected to a power source 24, and the lower electrode 23 is grounded.

The lower electrode 23 includes a base layer, a carrier layer configured to support an external glass substrate, a bolt fixedly connecting the base layer and the carrier layer.

The lower electrode 23 includes a sealing member sleeved on an outer peripheral side of the bolt. The sealing member includes a sealing body and a through hole disposed in the sealing body, and the bolt is adapted to pass through the through hole.

The carrier layer includes a connecting hole and a first counterbore communicating with an end of the connecting hole facing away from the base layer, and the bolt is adapted to pass through the connecting hole.

The bolt sequentially passes through the through hole and the connecting hole and is screwed with the base layer. The sealing body and a nut of the bolt are disposed in the first counterbore.

The sealing body completely covers an opening of the connecting hole.

In the dry etching machine of the embodiment, a shape of the sealing body is same as a shape of the first counterbore, and the sealing body is disposed in the first counterbore in an interference fit.

In the dry etching machine of the embodiment, the seal member is made of polyetheretherketone.

In the dry etching machine of the embodiment, the sealing member includes a receiving groove recessed in an end of the sealing body facing away from the base layer and communicating with the through hole, and the nut of the bolt is disposed in the receiving groove.

In an embodiment of the present disclosure, a thickness of the sealing member is same as a depth of the first counterbore.

In the dry etching machine of the embodiment, the lower electrode 23 further includes a sealing cover, the carrier layer includes a second counterbore disposed at an end of the first counterbore facing away from the base layer, and the sealing cover is sealingly disposed in the second counterbore.

In the dry etching machine of the embodiment, the base layer is an electrode, the carrier layer is a ceramic layer, the bolt is an insulating bolt, and the sealing cover is a ceramic cover.

Compared to the lower electrode of the dry etching machine of existing technologies, the lower electrode and the dry etching machine of the embodiment of the present disclosure, in one hand, use the sealing member to completely cover the opening of the connecting hole, so as to improve sealing of the sealing member and prevent plasma from entering the connecting hole and causing the lower electrode to be injured. On another hand, the sealing member is made of polyetheretherketone, so as to improve high temperature resistance and compressive strength of the sealing member and avoid deformation of the sealing member during high temperature operation and sealing loss of the sealing member, which may cause the lower electrode to be injured. The embodiment also solves technical problems that when an existing lower electrode is subjected to dry etching, plasma enters the connecting hole and reacts with the base layer, thereby causing the base layer to be injured.

The present disclosure has been illustrated and described with respect to one or more embodiments thereof, and equivalents and modifications will be apparent to those skilled in the art. The present disclosure includes all such modifications and variations and is only limited by the scope of the appended claims. Moreover, although certain features of the present disclosure have been disclosed with respect to only one of several implementations, such features may be combined with one or more other implementations as may be desired and advantageous for a given or particular application or other feature combinations. Moreover, the terms “comprising,” “having,” or “including” are used in the particular embodiments or claims, and such terms are intended to be encompassed in a manner similar to the term “comprising.”

In the above, the present disclosure has been disclosed in the above embodiments, and serial numbers before the embodiments, such as “first”, “second”, etc., are used for convenience of description only, and the order of the embodiments of the present disclosure is not limited. In addition, the above embodiments are not intended to limit the present disclosure, and it is understood that many changes and modifications to the described embodiment can be carried out without departing from the scope and the spirit of the disclosure that is intended to be limited only by the appended claims.

1. A lower electrode, comprising:
a base layer;
a carrier layer configured to support an external glass substrate;
a bolt fixedly connecting the base layer and the carrier layer; and
a sealing member sleeved on an outer peripheral side of the bolt, the sealing member comprising a sealing body and a through hole disposed in the sealing body, the bolt adapted to pass through the through hole;
wherein the carrier layer comprises a connecting hole and a first counterbore communicating with an end of the connecting hole facing away from the base layer, the bolt is adapted to pass through the connecting hole;
wherein the bolt sequentially passes through the through hole and the connecting hole, and is screwed with the base layer, the sealing body and a nut of the bolt are disposed in the first counterbore;
wherein the sealing body completely covers an opening of the connecting hole, a shape of the sealing body is same as a shape of the first counterbore, and the sealing body is disposed in the first counterbore in an interference fit;
wherein the seal member is made of polyetheretherketone.

2. The lower electrode according to claim 1, wherein the sealing member comprises a receiving groove recessed in an end of the sealing body facing away from the base layer and communicating with the through hole, and the nut of the bolt is disposed in the receiving groove.

3. The lower electrode according to claim 2, wherein a thickness of the sealing member is same as a depth of the first counterbore.

4. The lower electrode according to claim 1, wherein the lower electrode further comprises a sealing cover, the carrier layer comprises a second counterbore disposed at an end of the first counterbore facing away from the base layer, and the sealing cover is sealingly disposed in the second counterbore.

5. The lower electrode according to claim 4, wherein the base layer is an electrode, the carrier layer is a ceramic layer, the bolt is an insulating bolt, and the sealing cover is a ceramic cover.

6. A lower electrode, comprising:
a base layer;
a carrier layer configured to support an external glass substrate;
a bolt fixedly connecting the base layer and the carrier layer; and
a sealing member sleeved on an outer peripheral side of the bolt, the sealing member comprising a sealing body and a through hole disposed in the sealing body, the bolt adapted to pass through the through hole;
wherein the carrier layer comprises a connecting hole and a first counterbore communicating with an end of the connecting hole facing away from the base layer, the bolt is adapted to pass through the connecting hole;
wherein the bolt sequentially passes through the through hole and the connecting hole, and is screwed with the base layer, the sealing body and a nut of the bolt are disposed in the first counterbore;
wherein the sealing body completely covers an opening of the connecting hole.

7. The lower electrode according to claim 6, wherein a shape of the sealing body is same as a shape of the first counterbore, and the sealing body is disposed in the first counterbore in an interference fit.

8. The lower electrode according to claim 6, wherein the seal member is made of polyetheretherketone.

9. The lower electrode according to claim 6, wherein the sealing member comprises a receiving groove recessed in an end of the sealing body facing away from the base layer and communicating with the through hole, and the nut of the bolt is disposed in the receiving groove.

10. The lower electrode according to claim 9, wherein a thickness of the sealing member is same as a depth of the first counterbore.

11. The lower electrode according to claim 6, wherein the lower electrode further comprises a sealing cover, the carrier layer comprises a second counterbore disposed at an end of the first counterbore facing away from the base layer, and the sealing cover is sealingly disposed in the second counterbore.

12. The lower electrode according to claim 11, wherein the base layer is an electrode, the carrier layer is a ceramic layer, the bolt is an insulating bolt, and the sealing cover is a ceramic cover.

13. A dry etching machine, comprising:
a reaction chamber;
an upper electrode disposed at an upper portion of the reaction chamber; and
a lower electrode disposed at a lower portion of the reaction chamber;
wherein the upper electrode and the lower electrode are oppositely disposed, the upper electrode is connected to a power source, and the lower electrode is grounded;
wherein the lower electrode comprises a base layer, a carrier layer configured to support an external glass substrate, a bolt fixedly connecting the base layer and the carrier layer, and a sealing member sleeved on an outer peripheral side of the bolt;
wherein the sealing member comprises a sealing body and a through hole disposed in the sealing body, the bolt is adapted to pass through the through hole;
wherein the carrier layer comprises a connecting hole and a first counterbore communicating with an end of the connecting hole facing away from the base layer, the bolt is adapted to pass through the connecting hole;
wherein the bolt sequentially passes through the through hole and the connecting hole, and is screwed with the base layer, the sealing body and a nut of the bolt are disposed in the first counterbore;
wherein the sealing body completely covers an opening of the connecting hole.

14. The dry etching machine according to claim 13, wherein a shape of the sealing body is same as a shape of the first counterbore, and the sealing body is disposed in the first counterbore in an interference fit.

15. The dry etching machine according to claim 13, wherein the seal member is made of polyetheretherketone.

16. The dry etching machine according to claim 13, wherein the sealing member comprises a receiving groove recessed in an end of the sealing body facing away from the base layer and communicating with the through hole, and the nut of the bolt is disposed in the receiving groove.

17. The dry etching machine according to claim 16, wherein a thickness of the sealing member is same as a depth of the first counterbore.

18. The dry etching machine according to claim 13, wherein the lower electrode further comprises a sealing cover, the carrier layer comprises a second counterbore disposed at an end of the first counterbore facing away from the base layer, and the sealing cover is sealingly disposed in the second counterbore.

19. The dry etching machine according to claim 18, wherein the base layer is an electrode, the carrier layer is a ceramic layer, the bolt is an insulating bolt, and the sealing cover is a ceramic cover.
